(19) United States
(12) Patent Application Publication
(10) Pub. No.: US 2026/0032874 A1
(43) Pub. Date: Jan. 29, 2026

(54) Cooling Arrangement for an Electric Charger System

(71) Applicant: Caterpillar Inc., Peoria, IL (US)

(72) Inventor: Sweekar Bengaluru, Bengaluru (IN)

(73) Assignee: Caterpillar Inc., Peoria, IL (US)

(21) Appl. No.: 18/787,482

(22) Filed: Jul. 29, 2024

(51) Int. Cl. H05K 7/20

(52) U.S. Cl. CPC H05K 7/20936; H05K 7/20309; H05K 7/20318; H05K 7/20327; H05K 7/20354

(57) ABSTRACT

A field operable electric charger system includes a charger cooling arrangement having a liquid coolant circuit and an intermediate refrigerant circuit. The liquid coolant system directs a liquid coolant to a power conversion unit that converts electrical recharging power to for delivery and storing in a plurality of rechargeable electrical storage batteries. The liquid coolant absorbs thermal energy from the power conversion unit and a heat exchanger transfers the thermal energy from the liquid coolant to a refrigerant circulating in the refrigerant circuit. The thermal energy is discharge from the refrigerant to the ambient environment through a radiator.

### TECHNICAL FIELD

This patent disclosure relates generally to an electric charger system configured for field operation and, more particularly, to a cooling arrangement for thermal management of the electric charger system.

### BACKGROUND

Equipment and machines used at worksites like mining and construction are increasingly configured to operate using electrical power. In some instances, the equipment and machines may be mobile and able to travel about the worksite, in which case tethering the moveable equipment and mobile machines to an external source of electrical power is impractical. In such cases, the movable equipment and mobile machines may include an onboard source of electrical power such as, for example, one or more rechargeable electrical storage batteries that are associated with and electrically connected to an electric motor. The rechargeable storage batteries accommodate and convert latent chemical energy to electrical power that the electric motor can utilize to generate a motive force for work. When the rechargeable battery is depleted, it must be periodically recharged from another electrical source.

In large scale mining and construction sites, the external source of electrical power may be utility grid or large electrical generator the creates polyphase alternating current while the storage batteries on the moveable equipment and mobile machines may utilize direct current electricity. Moreover, the moveable equipment and mobile machines may move continuously about the worksite such that the periodic charging from an external source of electrical power is difficult. For example, in an underground mining operation, electrically powered machines and equipment such as underground mobile loaders and mobile boring drills operate far underground in tight confinements in which it is impractical to provide connections to external power sources. Similarly, in above ground mining operations or large-scale construction sites, in which the layout of the worksite continually changes during development, it may be impractical to provide a plurality of fixed charging stations connected to a continuous external power.

To provide a source of rechargeable electrical power for mobile equipment and machines in such remote or dynamically developing worksites, portable electric charger systems configured for field operation may be used. The field operable electric charger system is ruggedly configured for movement about the worksite and may include electrical devices configured to convert electrical power from an external source for utilization by the rechargeable electrical storage batteries.

To convert the electrical power from the line or source to high voltage direct current stored in the electrical storage batteries, the field operable electric charger system may include a power conversion assembly comprising a plurality of electrical devices capable of modifying the electrical power conducted. The power conversion assembly generates heat during operation that should be dissipated to the ambient environment. U.S. Pat. No. 8,893,552 describes a cooling system for a fixed and permanent electric charging system that is configured to cool the internal electrical devices. The present disclosure is directed to a cooling system configured to cool the power conversion assembly that may be particularly applicable to the size and portable characteristics of a field operable electric charger system.

### SUMMARY

The disclosure describes, in one aspect, an electric charger system configured for field operation that includes an exterior charger housing with a power inlet connector to connect with a power source for receiving electrical recharging power and a power outlet connector to connect with electrical equipment for recharging one or more rechargeable electrical storage batteries. The electrical charger system can also include a power conversion assembly for modifying the electrical recharging power directed from the power inlet connector to the power outlet connector. To cool the power conversion assembly, the electrical charger system also includes a charger cooling system having a liquid coolant circuit and an intermediate refrigerant circuit. The liquid coolant circuit has a coolant pump directing a liquid coolant to the power conversion assembly and the intermediate refrigerant circuit has a compressor directing a refrigerant to a condenser and a throttle valve receiving refrigerant from the condenser. To exchange thermal energy between the liquid coolant and the refrigerant, the charger cooling system includes a heat exchanger disposed between the liquid coolant circuit and the refrigerant circuit.

In another aspect, the disclosure describes a heat management process for a field operable electric charger system. The heat management process includes a liquid cooling step that directs a liquid coolant to a power conversion assembly converting electrical power to recharge one or more rechargeable electrical storage batteries in the field. The liquid coolant can absorb and remove thermal energy from the power conversion assembly. The heat management process also includes a heat exchange step transferring the thermal energy from the liquid coolant to a refrigerant. To discharge the thermal energy from the refrigerant to an ambient environment, the heat management system includes a heat discharging step.

In a further aspect, the disclosure describes a charger cooling system for a field operable electric charger system that includes a liquid coolant circuit and a refrigerant circuit respectively circulating a liquid coolant and a refrigerant. The liquid coolant circuit includes a coolant pump and an inlet manifold directing the liquid coolant to a power conversion assembly. The refrigerant circuit includes a heat exchanger for transferring thermal energy to the refrigerant from the liquid coolant and a radiator for discharging the thermal energy from the refrigerant to an ambient environment.

### BRIEF DESCRIPTION OF THE DRAWINGS

FIG. 1 is a perspective view of a field operative electric charger system designed to store and provide electric power to one or more items of electrically powered equipment operating in an inaccessible or seclude worksite.

FIG. 2 is a block diagram of the power conversion assembly of the electric charger system for electrically charging electrical storage batteries and that is associated with a cooling arrangement for transferring heat energy from the power conversion components.

FIG. 3 is a schematic diagram of the cooling arrangement including a liquid coolant circuit fluidly communicating with the power conversion components and a refrigerant circuit transferring heat energy to the ambient.

FIG. 4 is a block diagram of an embodiment of the fluid-to-fluid heat exchanger thermally coupling the liquid coolant circuit and the refrigerant circuit of the cooling arrangement for the electrical charger system.

FIG. 5 is a flowchart representing the possible transfer of thermal energy through the cooling arrangement for the electric charger system.

### DETAILED DESCRIPTION

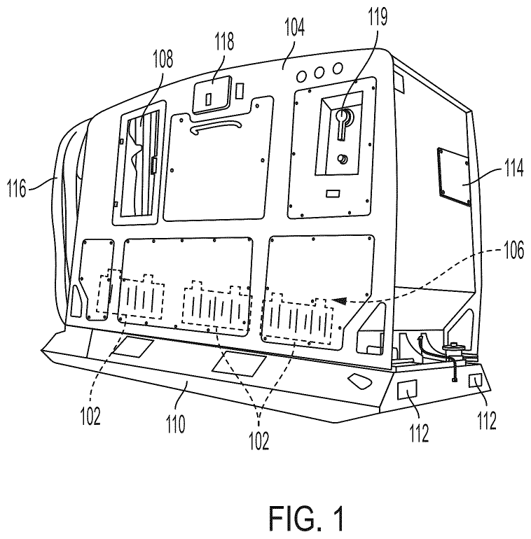

Now referring to the drawings, wherein whenever possible like reference numbers will refer to like elements, there is illustrated in FIG. 1 an energy storage system in the form of a field operative electric charger system 100 for converting and delivering electricity to electrically powered equipment operating in remote or secluded worksites. In particular, the electric charger system 100 is designed to receive and store electrical power from a primary source such as an electrical grid that may be operated by a utility or from a large-scale electric generation plant. The electric charger system 100 accommodates a plurality of electrical devices and components configured and arranged to convert the electrical power from the external source to power usable by the storage batteries on the mobile machines and equipment in the field. For example, the electric converter devices can change the current between alternating and direct current, and may adjust and modify the voltage to improve the charging rate.

In a possible example, the electric charger system 100 can include a plurality of electrical power storage devices such as rechargeable electric storage batteries 102 to facilitate the recharging process. The rechargeable, or secondary, electric storage batteries 102 can include a plurality individual electro-chemical cells that can be connected to an external circuit by conductive electrode terminals and that can undergo a reversible electrochemical reaction that alternately converts an electrical charge to chemical energy for storage and converts the chemical energy to electricity for discharge and powering electrical operated equipment. The rechargeable electric storage batteries can be configured to utilize any suitable type of electrochemistry such as lead acid or lithium-ion and can be selectively interconnected in parallel or series to adjust the power output characteristics of the electric charger system 100. In other examples, the storage batteries may be omitted and the electric charger system 100 can function mainly to adjust and convert electrical power from the source to the mobile machine and equipment.

To group together and accommodate the electrical converter devices and the rechargeable electric storage batteries 102 in a cooperative arrangement, the electric charger system 100 can include an exterior charger housing 104 that can be assembled from interconnected metal plates or panels that forms an external cover or structure that may have a generally overall orthogonal shape or design. The panels of the exterior charger housing 104 can define an interior compartment 106, which is an opened space to accommodate the electrical conversion devices and possibly the electric storage batteries 102. One or more of the panels of the exterior charger housing 104 can be removable to access the interior compartment 106 and one or more of the panels can be configured as a grill 108 or screen to allow airflow to transfer between the interior compartment 106 and the ambient environment.

Because the electrically operated equipment may be located at distant or remote areas about a mining site or large-scale construction operation, the field operative electric charger system 100 may be portable and configured for transportation about the worksite. The exterior charger housing 104 can be mounted on a skid 110 or frame that forms the base of the electric charger system 100 and is adapted for setting on the terrain surface about the worksite. The skid 110 can include parallel rails that are adapted to make sliding contact with the terrain surface, enabling the electric charger system 100 to be towed about the worksite. The skid 110 can also include a pair of fork apertures 112 that can receive the forked prongs from a forklift as another method of transporting the electric charger system 100 about the worksite. The charger housing 104 can also include one or more eyelifts to enable suspension lifting via cables.

To direct electrical power to and from the electrical storage batteries, the electric charger system 100 can include at least one power inlet connector 114 and at least one power outlet connector 116. The power inlet connector 114 can be positioned at an external and exposed location on the charger housing 104 and is adapted to electrically interface with and connect to a power source such as the power grid or an electrical generator. In an example, the power inlet connector 114 can be configured as an electrical socket that can mate with a corresponding plug to receive three-phase alternating current from the power source. To electrically connect with the electrically operable equipment in the field, the power outlet connector 116 can be configured as an electrical power cable flexibly extending from the charger housing 104.

To monitor the operating conditions and parameters of the electric charger system 100, an operator interface 118 can be positioned at an exposed location on the charger housing 104. The operator interface 118 can include a visible display screen that provides a visible readout about the operating state of the electric charger system 100, such as the charging level and storage capacity of the electric charger system 100. The operator interface 118 can also output and display information regarding the electrical characteristics associated with the electric charger system 100, such as the voltage, currently, frequency and/or phase of electricity being delivered to or discharged from the electrical charger system 100. The visual display may have touch screen capabilities, and the operator interface 118 can include keypads, buttons, dials and the like through which a human operator may interact to control and adjust operation of the electric charger system 100. To shut down electrical operation of the electric charger system 100, an electrical switch 119 can be positioned at an accessible location on the exterior charger housing 104 that may break or open any electrical circuit to which the electric charger system 100 may be connected.

Because storage batteries used on mobile equipment and movable machines typically operates on and store direct current electrical power, the electrical characteristics of the charging power received at the power inlet connectors 114, typically polyphase alternating current from a utility grid or generator, must be modified. The field operable electric charger system 100 can therefore include a power conversion assembly 120 that can be accommodated in the interior compartment 106 of the charger housing 104. The power conversion assembly 120 can be operatively disposed between the power inlet connector 114 and power outlet connector 116 to modify and adjust the electrical characteristics of the power transferred there between.

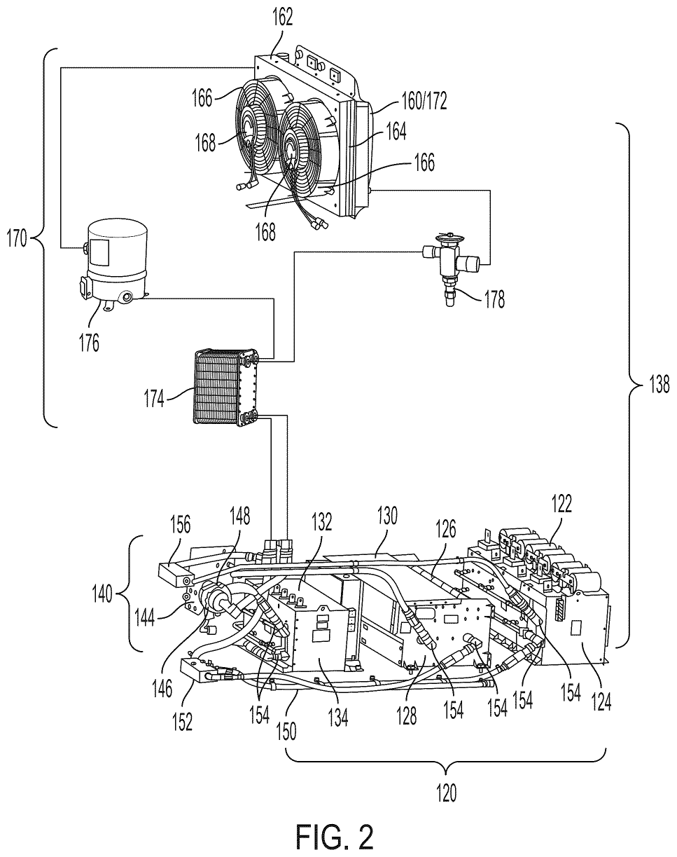

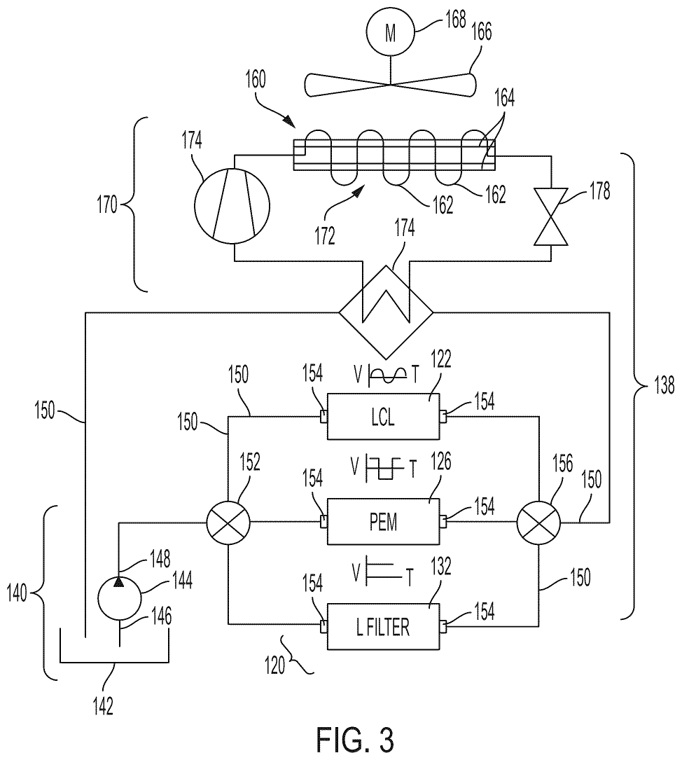

Referring to FIGS. 2 and 3, the power conversion assembly 120 can include a plurality of power conversion components and devices designed and configured to alter the charging power received by the electric charger system 100. For example, the power conversion assembly 120 can include a line filter, referred to as a LCL filter 122 that is comprised of inductors, capacitors, and possibly other electrical devices that are assembled together in a box-like first filter casing 124. The LCL filter 122 can transform the line current and voltage of the electrical recharging power received as sinusoidal varying alternating current at the power inlet connector 110 to pulse width modulated electrical recharging power characterized by periodic square waves. In the examples where the electrical recharging power is three-phase alternating current, the LCL filter 122 can include a pair of inductors and a capacitor for each phase.

To modify further the electrical recharging power for recharging electrical storage batteries, the power conversion assembly 120 can include a power electronic module, referred to as a PEM 126. The PEM 126 can include a plurality of convertors that converts the electrical recharging power to a format usable by the electrical storage batteries 102. For example, a functionality of the PEM 126 can be to convert the pulse width modified recharging power from the LCL filter 122 to a direct current form characterized by a constant current flow in the same continuous direction. To modify the electrical power directed there through, the PEM 126 can include a plurality of transistors such as IGBTs and similar electrical devices capable of rapid switching and arranged to create a rectifier. In addition, to create high voltage direct current that may be needed by the electrical equipment, the PEM 126 can be configured to step up or increase the electrical recharging power from the line voltage to 1500 V, for example.

The electrical devices that make up the PEM 126 can be contained and accommodated in a PEM casing 128 that is constructed as a metal box-like structure. Because the rapid switching of the IGBTs, the PEM 126 may generate a significant degree of thermal energy as heat. To remove the generated heat, the PEM 126 can include a heat sink 130 that, as described below, can interact and exchange thermal energy with a liquid coolant.

To further smooth the HVDC output from the PEM 126 for consistency, the power conversion assembly 120 can include an L-filter 132 or LC filter electrically connected downstream. The L-filter 132 is cable of cutting or eliminating any redundant ripples or frequencies in the electric recharging power before directing the power to the power outlet connector 112. The L-filter 132 can be comprised of inductors and possibly capacitors that are accommodated in a metallic, box-like second filter casing 134.

Because each of the components of the power conversion assembly 120 generates thermal energy in the form of heat, the electrical charger system 100 can include a charger cooling arrangement 138 that removes the thermal energy from the field operable electric charger system 100. For example, the charger cooling arrangement 138 can include a liquid coolant circuit 140 that utilizes a liquid coolant medium such as, for example, a glycol water mixture. In an example, the liquid coolant circuit 140 can include a coolant reservoir 142 or tank for accommodating the liquid coolant and a coolant pump 144 that pressurizes and directs the coolant flow to the power conversion assembly 120. The coolant reservoir 142 can be an enclosed tank or can be vented to atmosphere. In another example, the liquid coolant circuit 140 may have a closed circuit configuration with the total quantity of liquid coolant retained by the associated components and the reservoir 142 may be eliminated. The coolant pump 144 can be a centrifugal pump having an internal rotating impeller that draws coolant from the coolant reservoir through a central pump inlet 146 and discharges the coolant through circumferential pump outlet 148.

To direct the flow of liquid coolant to the electric conversion components of the power conversion assembly 120, the liquid coolant circuit 140 can include a plurality of coolant conduits 150, which may be embodied as flexible tubes or rigid pipes. The coolant conduits 150 can be attached to and in fluid communication with each of the LCL filter 122, the PEM 126, and the L-filter 132. In an example, to direct relatively cool liquid coolant to each of the power conversion components from the coolant reservoir 142, the liquid coolant circuit 140 can be fluidly arranged in parallel with each of the LCL filter 122, the PEM 126, and the L-filter 132. To distribute the liquid coolant in parallel, the liquid coolant circuit 140 can include a coolant intake manifold 152 that distributes the liquid coolant separately to each of the LCL filter 122, the PEM 126, and the L-filter 132 via the coolant conduits 150.

The coolant conduits 150 can be fluidly connected to each of the first filter casing 124, the PEM casing 128, and the second filter casing 134 by fluid fittings 154. The fluid fittings 154 can establish fluid communication with internal channel or conduits formed in each of the LCL filter 122, the PEM 126, and the L-filter 132 to circulate the liquid coolant therein and thereby absorb thermal energy from the respective power conversion component. To remove the heated liquid coolant, the liquid coolant circuit 140 can also include a coolant outlet manifold 156 that is connected in parallel to the LCL filter 122, the PEM 126, and the L-filter 132 via the coolant conduits 150.

To discharge the heat absorbed by the liquid coolant from the plurality of power conversion components, the liquid coolant circuit 140 can be operatively associated with a radiator 160. The radiator 160 can be configured to discharge heat from the liquid coolant to the ambient environment via thermal convection. To enable heat transfer to the ambient environment, the radiator 160 can be assembled from a plurality of thin-walled radiator conduits 162 fluidly interconnected together and integrally joined by a plurality of cooling fins 164 to increase the surface area. The radiator conduits 162 can be arranged to circulate the liquid coolant through several passes to increase the temporal duration during which thermal transfer may occur. To further increase the thermal transfer of heat from the liquid coolant, the radiator 160 can be operatively associated with one or more fans 166 that direct ambient air over the radiator conduits 162 and cooling fins 164. The fans 166 can also be arranged to direct airflow over the plurality of electrical storage batteries 102 to remove heat and cool the batteries. To exhaust heated air from or intake fresh air into the interior compartment 106 wherein the radiator 160 may be located, the radiator 160 can be positioned proximate to one of the grills 108 on the charger housing 104.

To improve the thermal transfer of heat energy from the power conversion assembly 120 to the ambient environment, the charger cooling arrangement 138 can also include an intermediate refrigerant circuit 170 that is located between and thermally connected to the liquid coolant circuit 140 and the radiator 160. The intermediate refrigerant circuit 170 functions to transfer heat energy from the heated liquid coolant collected at and flowing from the outlet manifold 156 to the radiator 160 and discharges the heated energy through the radiator. In an example, the intermediate refrigerant circuit 170 can be classified as a vapor compression cycle that is characterized by two heat exchangers and a fluid medium such as a refrigerant that transitions between liquid and vapor phases as it cycles between the two heat exchangers; however in other examples, the intermediate refrigerant circuit 170 may operate using other refrigerant cycles.

In the illustrated example of the intermediate refrigerant circuit 170, the two heat exchangers can be embodied as a condenser 172 in which the vapor refrigerant undergoes a phase transition from the vapor to a liquid and an evaporator 174 in which the fluid refrigerant undergoes a phase transition that evaporates the refrigerant from liquid to vapor. The vapor-to-liquid phase transition in the condenser 172 is typically exothermic and characterized as discharging and releasing heat and the liquid-to-vapor transition via evaporation in the evaporator 174 is typically endothermic and characterized by absorbing heat. Hence, the evaporator 174 can remove heat from the liquid coolant circuit 120 and the condenser 174 releases or discharges heat to the radiator 160.

To complete the alternating and cyclic transitioning of the fluid refrigerant between the vapor phase and the liquid phase, the refrigerant circuit 170 can include components referred to as a compressor 176 and a throttle or expansion valve 178 that are disposed in fluid communication with the condenser 172 and the evaporator 174. The compressor 176 is located downstream of the evaporator 174 and functions to increase the pressure of the heated vapor-phase refrigerant received from the evaporator 174. The compressor 176 is a mechanical device similar to a pump that compresses or reduces the volume of the compressible vapor phase refrigerant resulting in the proportional increase in its pressure. The compressed refrigerant is discharged from the compressor as a super-heated, high-pressure gas that is fluidly directed to the condenser 174.

The expansion valve 178 is located downstream of the condenser 172 and receives high-pressure condensed refrigerant in the liquid phase. To reduce the pressure of the refrigerant directed to the evaporator 174, the expansion valve 178 can meter or reduce the flow volume or quantity of the liquid refrigerant. Reducing the volume of refrigerant present in the evaporator 174 enables endothermic evaporation to the vapor phase to occur. The expansion valve 178 can include a fluid feedback conduit or the like that fluidly interconnects between the high-pressure upstream and low-pressure downstream sides of the expansion valve to regulate the fluid pressure.

To fluidly interconnect the components of the intermediate refrigerant circuit 170, fluid conduits 179 such as rigid tubular pipes or flexible hoses may be used. The materials and structural arrangement of the components and conduits 179 can be configured to address the cyclic pressure and phase change and material resiliency to the refrigerant medium. To facilitate regulation of the intermediate refrigerant circuit 170, temperature and pressure sensors can be disposed at various positions in the fluid conduits 179.

To fluidly couple and link the liquid coolant circuit 140 and the intermediate refrigerant circuit 170, the evaporator 174 can be dispose between them and configured to transfer thermal energy between the circuits. For example, the evaporator 174 can be configured as a liquid-to-liquid heat exchanger in which the liquid coolant is directed to flow in close proximity to the liquid phase refrigerant. The liquid-to-liquid heat exchanger is configured to maintain fluid separation of the two fluid mediums while enabling thermal heat transfer between them. The liquid-to-liquid heat exchanger can have any suitable configuration such as cross-flow, counter-flow, parallel flow, etc.

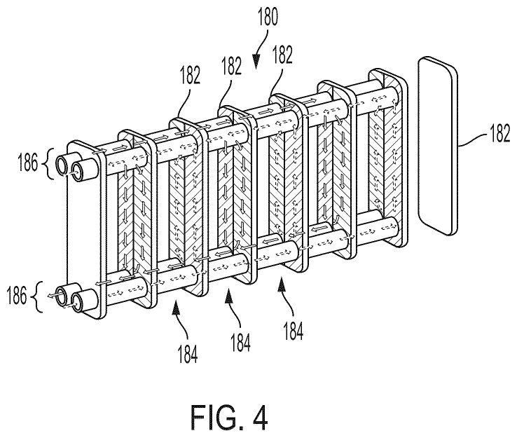

In a particular example, the liquid-to-liquid heat exchanger functioning as the evaporator 174 can be a microplate exchanger 180. Referring to FIG. 4, the microplate exchanger 180 can include a plurality of thin metal plates 182 of similar shape and size that are arranged in a parallel stacked configuration. The plurality of parallel metal plates 182 are separated and spaced apart from each other to provide fluid channel 184 that accommodate fluids. In particular, the planar surfaces of the metal plates 182 can be formed with grooves disposed therein or raised dimples protruding therefrom that provide the separation to create the fluid channels 184. The fluid channels 184 can be sealed by gaskets that are disposed between the parallel metal plates. To communicate with the isolated fluid channel 184, one or more fluid ports 186 in the formed of elongated conduits or pipes traverse the plurality of metal plates 182.

In operation, the heated liquid coolant from the outlet manifold 156 of the liquid coolant circuit 140 can flow through a designated subset of the fluid channels 184 and the low-pressure liquid refrigerant can flow through a parallel, alternative subset of fluid channels arranged in an alternating configuration. The metal plates 182 physically separate the flowing fluids in the fluid channels while allowing thermal transfer of heat energy between them. The heat transfer can cause the low-pressure liquid refrigerant in the designated fluid channels 184 to evaporate into the vapor phase that may be discharged from the microplate heat exchanger 180 to the compressor 176. An advantage of the microplate heat exchanger 180 is that the surface area of the metal plates 182 provides increased thermal transfer while maintaining a compact, small-scale configuration resulting in greater efficiency based on size to heat transfer considerations. Moreover, the microplate exchanger 180 may be readily scalable for different flow quantities and volumes by adding or removing metal plates 182 and thus fluid channels 184.

To release the heat energy entrained in the vaporized refrigerant flowing from the evaporator 174 through an exothermic reaction, the condenser 172 of the intermediate refrigerant circuit 170 can be structurally combined with the radiator 160. For example, the pressurized vapor-phase refrigerant discharged by the compressor 176 can be directed through the plurality of thin-walled radiator conduits 162. The significant surface area provided by the thin-walled radiator conduits 162 initiates and allows the vaporized refrigerant to condense to the liquid phase releasing the thermal heat energy. The thermal energy is conductively transferred to the cooling fins 164 then transferred by convection to the ambient environment. The fans 166 may increase the airflow through the radiator 160 increasing thermal convection and heat transfer efficiency.

### INDUSTRIAL APPLICABILITY

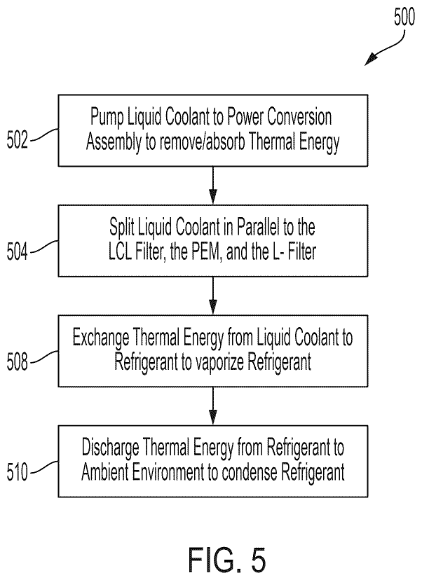

Illustrated in FIG. 5, with continued reference to the proceeding figures, there is shown a flow diagram of the cooling process or method of heat management for a field operable electric charger system 100 for recharging electrical storage batteries that comprises an active power conversion assembly 120 including a plurality of heat generating electric devices. The heat management process 500 is characterized by cooperatively combining and utilizing a liquid coolant circuit 140 using a liquid coolant in direct fluid communication with the power conversion assembly 120 and the intermediate refrigeration circuit 170 utilizing a vapor compression cycle. The liquid coolant remains in the liquid phase during circulation through the liquid coolant circuit 140 while the refrigerant undergoes phase transitions between liquid and vapor phases in the intermediate refrigerant circuit 170.

To remove heat energy from the plurality of electrical devices, the heat management process 500 begins with a liquid cooling step 502 or operation in which liquid coolant, such as a glycol-water mixture, is directed to the power conversion assembly 120 by the coolant pump 144. The glycol-water mixture comprising the liquid coolant can be characterized by a significantly high specific heat capacity to receive and retain thermal energy from the different electric devices, thereby cooling the power conversion assembly 120.

In a particular example wherein the power conversion assembly 120 is comprised of a plurality of heat generating electrical devices including the LCL filter 122, the PEM 126, and the L-filter 132, the heat management process 500 may include a coolant splitting sub-step 504 or operation in which the inlet manifold 152 splits and directs the liquid coolant into a plurality of coolant conduits 150. The coolant splitting sub-step 504 results in establishing and directing liquid coolant in parallel and separately to each of the LCL filter 122, the PEM 126, and the L-filter 132, so that each electrical component receives liquid coolant at a common reduced temperature.

The LCL filter 122, the PEM 126, and the L-filter 132 may differ in the quantity and temperature of heat generated. Accordingly, the coolant splitting sub-step 504 can direct different quantities of liquid coolant to each of the electrical devices of the power conversion assembly 120. For example, the PEM 126 that is comprised of a plurality of active switching devices such as IGBTs may generate significantly more heat than the passive LCL filter 122 or the passive L-filter 132. In an example, the PEM 126 might generate two thirds to three quarters of the total heat creation of the power conversion assembly 120 while the LCL filter 122 and the L-filter 132 are only responsible for the remaining third or quarter.

The inlet manifold 152 is therefore configured to direct different volumes or flow rates of the liquid coolant to each of the LCL filter 122, the PEM 126, and the L-filter 132. For example, the coolant splitting sub-step 504 may result in directing approximately 50% or one half of the total flow of liquid coolant from the coolant pump 144 to the PEM 126 while the remaining 50% is split between the LCL filter 122 and the L-filter 132, for instance at 25% each. In another example, the coolant splitting sub-step 504 may direct approximately two thirds or 66% of the liquid coolant to the PEM 126 while the remaining one third is split and directed between the LCL filter 122 and the L filter 132, for instance at 16.5% each. In a possible configuration, the inlet manifold 152 may be adjustable and able to change the quantity or flow rate of liquid coolant directed between the LCL filter 122, the PEM 126, and the L-filter 132. The liquid coolant system 140 can include one or more temperature sensors that the coolant splitting sub-step 504 uses for active monitoring and to variably adjust the flow of liquid coolant from the adjustable inlet manifold 152.

In a heat exchange step 508 or operation, the heat management process 500 causes the thermal transfer of heat from the liquid coolant circuit 140 to the intermediate refrigerant circuit 170 via the evaporator 174. The heat exchange step 508 results in evaporation of the low pressure liquid refrigerant to high pressure vapor refrigerant at an elevated temperature. Correspondingly, the temperature of the liquid coolant is reduced and can be recirculated through the liquid coolant circuit 140 to repeatedly cool the power conversion assembly 120.

To finally discharge the thermal energy to the ambient environment, the heat management process 500 includes a heat discharge step 510 in which the vaporized and compressed refrigerant is directed through the radiator 160 that is structurally combined with and functions as the condenser 172. The phase transition from the vaporize refrigerant to the liquid phase in the radiator 160/condenser 172 increases the thermal transfer and discharge rate to the ambient.

A possible advantage of utilizing the intermediate refrigerant circuit 170 is that the increased rate of thermal transfer accompanying the phase transition from the vapor to the liquid refrigerant through the condenser 172 can reduce the size of the radiator 160, which is beneficial due to the size and weight consideration associated with the field operator electric charger system 100. A possible related advantage is that the intermediate refrigerant circuit 170 can be physically isolated from the power conversion assembly 120, thereby reducing or eliminating material compatibility issues between refrigerant and the LCL filter 122, the PEM 126, and the L-filter 132.

It will be appreciated that the foregoing description provides examples of the disclosed system and technique. However, it is contemplated that other implementations of the disclosure may differ in detail from the foregoing examples. All references to the disclosure or examples thereof are intended to reference the particular example being discussed at that point and are not intended to imply any limitation as to the scope of the disclosure more generally. All language of distinction and disparagement with respect to certain features is intended to indicate a lack of preference for those features, but not to exclude such from the scope of the disclosure entirely unless otherwise indicated.

Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context.

The use of the terms “a” and “an” and “the” and “at least one” or the term “one or more,” and similar referents in the context of describing the invention (especially in the context of the following claims) are to be construed to cover both the singular and the plural, unless otherwise indicated herein or clearly contradicted by context. The use of the term “at least one” followed by a list of one or more items (for example, “at least one of A and B” or one or more of A and B”) is to be construed to mean one item selected from the listed items (A or B) or any combination of two or more of the listed items (A and B), unless otherwise indicated herein or clearly contradicted by context.

Accordingly, this disclosure includes all modifications and equivalents of the subject matter recited in the claims appended hereto as permitted by applicable law. Moreover, any combination of the above-described elements in all possible variations thereof is encompassed by the disclosure unless otherwise indicated herein or otherwise clearly contradicted by context.

We claim:

1. An electric charger system configure for field operation comprising:
an exterior charger housing including a power inlet connector adapted for electrically connecting with a power source for receiving electrical power and a power outlet connector adapted for electrically connecting with electrical equipment to discharge the electrical;
a power conversion assembly for modifying the electrical power directed between the power inlet connector and the power outlet connector; and
a charger cooling system including:
a liquid coolant circuit having a coolant pump directing a liquid coolant to the power conversion assembly;
a refrigerant circuit having a compressor for directing a refrigerant to a condenser and a throttle valve receiving refrigerant from the condenser; and
a heat exchanger transferring thermal energy between the liquid coolant and the refrigerant.

2. The electric charger system of claim 1, wherein the heat exchanger is a liquid-to-liquid heat exchanger.

3. The electric charger system of claim 2, wherein the condenser directs refrigerant in a vapor phase to the condenser and the throttle valve receives refrigerant in a liquid phase from the condenser.

4. The electric charger system of claim 3, wherein the liquid-to-liquid heat exchanger functions as an evaporator in which the refrigerant transitions between the liquid phase and the vapor phase.

5. The electric charger system of claim 4, wherein the liquid-to-liquid heat exchanger is a microplate heat exchanger having a plurality of metal plates arranged in parallel and separated to form a plurality of fluid channels.

6. The electric charger system of claim 1, wherein the condenser functions as a radiator releasing thermal energy to an ambient environment associated with the exterior charger housing.

7. The electric charger system of claim 1, wherein the liquid coolant is a glycol-water mixture and the refrigerant is one of R12, R123, and R132.

8. The electric charger system of claim 1, wherein the power conversion assembly includes an LCL filter of convert the electrical recharging power from alternating current to pulse width modulated current, a PEM to convert the electrical recharging power from pulse width modified current to direct current, and a L-filter for smoothing the electrical recharging power.

9. The electric charger system of claim 8, wherein the liquid coolant system includes an inlet manifold directing the liquid coolant in parallel to the LCL filter, the PEM, and the L-filter.

10. The electrical charger system of claim 9, wherein the inlet manifold directs 50% or more of the liquid coolant to the PEM.

11. A heat management process for a field operable electric charger system comprising:
a liquid cooling step directing a liquid to a power conversion assembly for converting electrical power to recharge one or more rechargeable electrical storage batteries to absorb and remove thermal energy from the power conversion assembly;
a heat exchange step transferring the thermal energy from the liquid coolant to a refrigerant; and
a heat discharging step discharging step releasing the thermal energy from the refrigerant to an ambient environment.

12. The heat management process of claim 11, wherein the heat exchange step occurs in a liquid-to-liquid heat exchanger.

13. The heat management process of claim 12, wherein the refrigerant transitions between a liquid phase and a vapor phase during the heat exchange step.

14. The heat management process of claim 13, wherein the refrigerant condenses from the vapor phase to the liquid phase during the heat discharge step.

15. The heat management process of claim 11, wherein the power conversion assembly includes an LCL filter, a PEM, and a L-filter.

16. The heat management process of claim 15, further comprising a coolant splitting sub-strep in which the liquid coolant is directed in parallel to each of the LCL filter, the PEM, and the L-filter.

17. The heat management process of claim 16, wherein the coolant splitting sub-step directs 50% or more of the liquid coolant to the PEM.

18. A charger cooling system for a field operable electric charger system comprising:
a liquid coolant circuit for circulating a liquid coolant, the liquid coolant circuit including a coolant pump, an inlet manifold directing the liquid coolant to a power conversion assembly, and an outlet manifold receiving the liquid coolant from the power conversion assembly; and
a refrigerant circuit for circulating a refrigerant, the refrigerant circuit including an heat exchanger for transferring thermal energy to the refrigerant from the liquid coolant and a radiator for discharging the thermal energy from the refrigerant to an ambient environment.

19. The charger cooling system of claim 18, wherein the heat exchanger is an evaporator in which the refrigerant transitions from a liquid phase to a vapor phase, and the radiator is a condenser in which the refrigerant condenses from the vapor phase condenses to the liquid phase.

20. The charger cooling system of claim 19, in which the power conversion assembly includes a LCL filter, a PEM, and a L-filter, and the inlet manifold directs liquid coolant in parallel to each of the LCL filter, the PEM, and the L-filter.

21. The charger cooling system of claim 20, wherein the inlet manifold directs 50% or more of the liquid coolant to the PEM.
